(19) United States
(12) Patent Application Publication
(10) Pub. No.: US 2025/0031398 A1
(43) Pub. Date: Jan. 23, 2025

(54) GAN-BASED HEMT STRUCTURE HAVING MULTI-THRESHOLD VOLTAGE, AND PREPARATION METHOD AND APPLICATION THEREFOR

(71) Applicants: Guangdong Institute of Semiconductor Micro-Nano Manufacturing Technology, Foshan (CN); SUZHOU INSTITUTE OF NANO-TECH AND NANO-BIONICS (SINANO) , CHINESE ACADEMY OF SCIENCES, Suzhou (CN)

(72) Inventors: Yaozong ZHONG, Foshan (CN); Qian SUN, Foshan (CN); Hongwei GAO, Foshan (CN); Xiaolu GUO, Foshan (CN); Xin CHEN, Foshan (CN); Yong YANG, Foshan (CN); Hui YANG, Foshan (CN)

(73) Assignees: Guangdong Institute of Semiconductor Micro-Nano Manufacturing Technology, Foshan (CN); SUZHOU INSTITUTE OF NANO-TECH AND NANO-BIONICS (SINANO) , CHINESE ACADEMY OF SCIENCES, Suzhou (CN)

(21) Appl. No.: 18/281,316

(22) PCT Filed: Sep. 7, 2022
(86) PCT No.: PCT/CN2022/117566

§ 371 Date: Sep. 11, 2023

(30) Foreign Application Priority Data
Jul. 7, 2022 (CN) 202210808044.1

(51) Int. Cl. H01L 29/66; H01L 27/088; H01L 29/20; H01L 29/778

(52) U.S. Cl. CPC H01L 29/66462; H01L 27/088; H01L 29/2003; H01L 29/7786

(57) ABSTRACT

A GaN-based High Electron Mobility Transistor (HEMT) having a multi-threshold voltage, a preparation method, and an application therefor are provided. The HEMT structure includes a channel layer and a barrier layer; a Two-dimensional Electron Gas (2DEG) is formed between the channel layer and the barrier layer; the barrier layer is at least provided with a first source area, a second source area, a first gate area, a second gate area, a first drain area, and a second drain area; the first source area, the first gate area, and the first drain area cooperate with each other, so as to form a first HEMT unit; the second source area, the second gate area, and the second drain area cooperate with each other, so as to form a second HEMT unit. that the HEMT may well meet application requirements of high and low threshold logic circuits.

### CROSS REFERENCE TO THE RELATED APPLICATIONS

This application is the national phase entry of International Application No. PCT/CN2022/117566, filed on Sep. 7, 2022, which is based upon and claims priority to Chinese Patent Application No. 202210808044.1, filed on Jul. 7, 2022, the entire contents of which are incorporated herein by reference.

### TECHNICAL FIELD

The application relates to a High Electron Mobility Transistor (HEMT) device structure, and specifically, to a GaN-based HEMT structure having a multi-threshold voltage, and a preparation method and an application therefor, which belongs to the technical field of semiconductors.

### BACKGROUND

Group III nitride semiconductors represented by GaN are called the third-generation semiconductors, which have the advantages of large band gaps, good chemical stability and high breakdown voltage. In addition, GaN-based HEMTs made of heterojunctions such as AlGaN/GaN have the advantages of high electron concentration and mobility, and have excellent performance in terms of high frequency, high withstand voltage, low on-resistance. The GaN-based HEMTs may be used as core devices of various power conversion systems and radio-frequency power amplifier systems, and have broad prospects in application fields such as consumer electronics, industrial electronics, and automotive electronics.

In the fields such as power electronics and radio-frequency electronics, in order to achieve certain specific functions such as signal noise reduction and operational amplification, a logic functional circuit generally needs to be integrated in a chip. In a modern large-scale integrated circuit based on silicon, a basic unit of a logic circuit is formed by a N-channel Metal-Oxide-Semiconductor Field Effect Transistor (N-MOSFET) and a P-channel Metal-Oxide-Semiconductor Field Effect Transistor (P-MOSFET), that is, a Complementary Metal-Oxide-Semiconductor (C-MOS) circuit (which is a complementary logic circuit), having the advantages of low power consumption and high integration. The N-MOSFET is a field effect transistor that is prepared by inverting electrons as conductive channels on a p-type silicon material; and the P-MOSFET is a field effect transistor that is prepared by inverting holes as conductive channels on a n-type silicon material. However, since there are many defective states in a GaN-based material, non-doped GaN often shows weak n-type, and due to incomplete ionization properties of acceptor Mg impurities, the p-type material needs to be doped with high-concentration Mg. In addition, the bulk mobility of holes in the GaN is very low, which is generally at 1-10 cm2/(V·s). Therefore, due to a large band gap of the GaN material and lack of a reliable gate dielectric material, it is difficult to achieve a solution of using a semiconductor to perform inversion or strong inversion so as to generate electrons or holes, and in particular, it is almost impossible to generate holes with high mobility.

At present, a solution for implementing an N-MOSFET in a GaN system mainly includes: using, as a conductive channel, Two-dimensional Electron Gas (2DEG) induced by an AlGaN/GaN heterojunction polarization effect, and realizing an enhanced n-FET with a threshold voltage being positive by using technical solutions such as a groove gate and a p-type gate, so as to achieve the properties of the N-MOSFET of turning on at high level and turning off at low level. A solution for implementing a P-MOSFET mainly includes: using, as a conductive channel, two-dimensional hole gas induced by a p-GaN/AlGaN heterojunction polarization effect, and realizing an enhanced p-FET with a threshold voltage being negative by using gate technologies such as the groove gate and an ion-implanted gate, so as to achieve the properties of a P-MOS transistor of turning on at high level and turning off at low level. Then, the n-FET and the p-FET are connected in series to construct a complementary logic circuit unit, so as to finally achieve related functional circuit design and manufacturing. However, there are still many technical difficulties in preparation of GaN-based n-FET and p-FET complementary logic circuits (Logic 0/1).

Currently, in a silicon semiconductor technology, there is a logic circuit based on low and high threshold voltage devices (Logic 1/2), referring to FIG. 1. Enhanced transistors (a n-FET 1 and a n-FET 2) with different threshold voltages are used to manufacture a logic circuit functional unit, operation processing of signals is implemented by using switch state differences of the transistors at different gate voltages. Such circuit design does not need the GaN-based p-FET, such that the logic circuit may have the ability to perform fast operations. However, high and low threshold logic circuits need to stably, uniformly implement devices with at least two different threshold voltages in the same wafer, or even a very small area.

To sum up, the performance requirements of an existing GaN-based complementary logic circuit technology for GaN-based p-FETs and the technical requirements of existing high and low threshold logic circuits pose a great challenge for the manufacturing of current GaN-based HEMT devices. Details are as follows.

First, the GaN-based p-FET in the complementary logic circuit technology generally uses bulk holes in p-type GaN or two-dimensional hole gas at a p-GaN/AlGaN interface, which has a very low mobility of around 10 cm²/(V's) at room temperature and up to 50 cm²/(V·s), and has a huge difference from the AlGaN/GaN-induced 2DEG that typically has a mobility of 1500 cm²/(V's). However, the ultimate operational speed of a logic operational circuit is strongly associated with the mobility of carriers in a semiconductor material; and if the mobility of the carriers is higher, the ultimate operational speed of the circuit is faster. Therefore, the ultimate operational speed of the logic circuit formed by the GaN-based p-FET and n-FET is limited to the mobility of the two-dimensional hole gas, such that it is difficult to take advantage of a GaN material system.

Second, the GaN-based p-FET in the complementary logic circuit technology requires a high-quality p-GaN ohmic contact. However, the current preparation of the p-GaN ohmic contact requires a p-GaN surface layer to be heavily doped with Mg to above 10²⁰ cm⁻³ and also requires use of metals with high work functions, such as Ni, Pd, etc. Contact resistivity is also generally above 10⁻⁴ Ω·cm² when a preparation condition is relatively harsh, and higher contact resistivity leads to larger power losses. In addition, due to preparation processes, the thermal stability of the p-GaN ohmic contact is relatively poor, and unsuitable for harsh operating environments.

Third, a p-FET gate in the complementary logic circuit technology is mostly prepared by processes such as etching and ion implantation, resulting in problems of uniformity and reliability. When a GaN dry etching method is used to reduce a p-FET gate area or ion implantation is used to perform acceptor compensation on the p-GaN, it is difficult to avoid lattice damage and surface staining to a GaN layer, introducing a gate interface state, causing device performance deterioration problems such as threshold voltage drift and large leakage, and the performance of the prepared p-FET is difficult to meet the requirements of logic operations.

Fourth, the high and low threshold logic circuit technology requires to implement enhanced device (for example, devices with a threshold voltage>1 V and >2 V) with high and low threshold voltages on the same wafer, and requires extremely high uniformity and reliability. For GaN-based devices, there is no perfect solution.

### SUMMARY

The present application is mainly intended to provide a GaN-based HEMT structure having a multi-threshold voltage, and a preparation method therefor, to overcome deficiencies in the related art.

In order to implement the foregoing objective of the present application, the technical solutions used in the present application include the following.

One aspect of the present application provides a GaN-based HEMT structure having a multi-threshold voltage. The HEMT structure includes a channel layer and a barrier layer. A 2DEG is formed between the channel layer and the barrier layer; the barrier layer is at least provided with a first source area, a second source area, a first gate area, a second gate area, a first drain area, and a second drain area; the first source area, the first gate area, and the first drain area cooperate with each other, so as to form a first HEMT unit, and the first HEMT unit has a first threshold voltage; the second source area, the second gate area, and the second drain area cooperate with each other, so as to form a second HEMT unit, and the second HEMT unit has a second threshold voltage; and the thickness of the barrier layer in the first gate area is less than that in the second gate area, so as to enable the first threshold voltage to be higher than the second threshold voltage.

Another aspect of the present application provides a method for preparing a GaN-based HEMT structure having a multi-threshold voltage. The method includes the following operations.

A channel layer and a barrier layer are sequentially grown on a substrate.

A first source area, a second source area, a first gate area, a second gate area, a first drain area, and a second drain area are at least defined on the barrier layer, where the first source area, the first gate area, and the first drain area cooperate with each other, so as to form a first HEMT unit, the second source area, the second gate area, and the second drain area cooperate with each other, so as to form a second HEMT unit, the first HEMT unit has a first threshold voltage, and the second HEMT unit has a second threshold voltage.

When the barrier layer is grown, the thickness of the barrier layer in the first gate area is enabled to be less than that in the second gate area, or after the barrier layer is grown, a local area of the barrier layer is removed, to enable the thickness of the barrier layer in the first gate area to be less than that in the second gate area, so as to enable the first threshold voltage to be higher than the second threshold voltage.

Still another aspect of the present application provides a GaN-based HEMT device, which includes the GaN-based HEMT structure having a multi-threshold voltage, and a plurality of gates, a plurality of sources, and a plurality of drains that cooperate with the HEMT structure.

Still another aspect of the present application provides an application of the GaN-based HEMT structure having a multi-threshold voltage in manufacturing of high and low threshold logic circuits.

Compared with the related art, firstly, according to the present application, an enhanced GaN-based HEMT structure with more than two threshold voltages can be implemented on the same wafer, and a preparation process is compatible with a preparation process of conventional group III-V semiconductor devices, such that the HEMT structure is suitable for industrial production; secondly, the barrier layer of the GaN-based HEMT may be an AlGaN/GaN/AlGaN composite structure, and an introduced GaN insertion layer may be used as a sacrificial layer for etching and thermal decomposition in the first gate area, such that the thickness of the AlGaN barrier layer in the gate area can be guaranteed, etching damage can be effectively removed, and a good guarantee is formed for the uniformity of the threshold voltage and the reliability of devices; furthermore, compared with a circuit in which a depleted/enhanced GaN HEMT forms a cooperation, the circuit in which the enhanced GaN HEMT with two threshold voltages implemented in the present application form a cooperation has lower power consumption and higher safety; and finally, the two enhanced GaN HEMTs implemented in the present application both use high-mobility 2DEG as the conductive channels, which have the capabilities of rapid on-off, and the logic circuit manufactured through cooperation has a faster calculation speed and a stronger anti-interference capability. Therefore, the present application can well meet application requirements of high and low threshold logic circuits.

### BRIEF DESCRIPTION OF THE DRAWINGS

In order to describe the technical solutions in embodiments of the present application more clearly, the drawings required to be used in the embodiments will be simply introduced below. It is apparent that the drawings in the following descriptions are only some embodiments of the present application. Those of ordinary skill in the art may further obtain other drawings according to these drawings without creative work.

FIG. 1 is a schematic diagram of a logic unit consisting of an HEMT with a multi-threshold voltage in the related art.

FIG. 2 is a schematic diagram of an epitaxial structure of a GaN-based HEMT device according to Embodiment 1.

FIG. 3 is a schematic diagram of a groove structure manufactured in a first gate area of the epitaxial structure shown in FIG. 2.

FIG. 4 is a schematic diagram of a secondary epitaxial P-type layer on the epitaxial structure shown in FIG. 3.

FIG. 5 is a schematic diagram of a P-type gate manufactured on a device structure shown in FIG. 4.

FIG. 6 is a schematic structural diagram of a GaN-based HEMT device according to Embodiment 1.

FIG. 7 is a schematic structural diagram of a GaN-based HEMT device according to Embodiment 2.

FIG. 8 is a schematic structural diagram of a GaN-based HEMT device according to Embodiment 3.

FIG. 9 is a schematic structural diagram of a GaN-based HEMT device according to Embodiment 4.

FIG. 10 is a schematic structural diagram of a GaN-based HEMT device according to Embodiment 5.

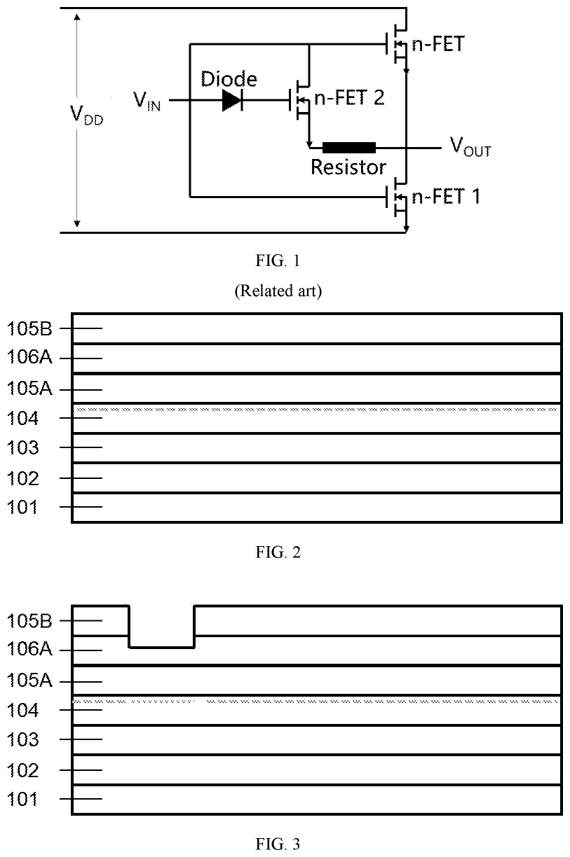

### DETAILED DESCRIPTION OF THE EMBODIMENTS

A GaN-based HEMT structure having a multi-threshold voltage provided in some embodiments of the present application includes a channel layer and a barrier layer. A 2DEG is formed between the channel layer and the barrier layer; the barrier layer is at least provided with a first source area, a second source area, a first gate area, a second gate area, a first drain area, and a second drain area; the first source area, the first gate area, and the first drain area cooperate with each other, so as to form a first HEMT unit, and the first HEMT unit has a first threshold voltage; the second source area, the second gate area, and the second drain area cooperate with each other, so as to form a second HEMT unit, and the second HEMT unit has a second threshold voltage; and the thickness of the barrier layer in the first gate area is less than that in the second gate area, so as to enable the first threshold voltage to be higher than the second threshold voltage.

In an embodiment, the barrier layer is further provided with a third source area, a third gate area, and a third drain area; the third source area, the third gate area, and the third drain area cooperate with each other, so as to form a third HEMT unit, and the third HEMT unit has a third threshold voltage; and the thickness of the barrier layer in the second gate area is less than that in the third gate area, so as to enable the first threshold voltage>the second threshold voltage>the third threshold voltage.

In the present application, according to a similar method, other gate areas on the barrier layer other than the first gate area, the second gate area, and the third gate area may also be defined, so as to form other HEMT units other than the first HEMT unit, the second HEMT unit, and the third HEMT unit. By enabling the barrier layer to have different thicknesses in different gate areas, the threshold voltage of each HEMT unit is regulated, such that the GaN-based HEMT structure having a multi-threshold voltage, with good uniformity and high reliability, may be obtained on the basis of the same wafer.

In an embodiment, the HEMT structure further includes a P-type layer. The P-type layer is disposed on a plurality of gate areas of the barrier layer, and is configured to reduce or exhaust the 2DEG under the plurality of gate areas of the barrier layer.

Further, a groove structure is formed in at least one gate area of the barrier layer; and the P-type layer distributed on the gate area is at least partially filled in the groove structure.

Compared with an existing GaN-based p-FET, the HEMT structure of the present application is a n-FET, and implements different threshold voltages by epitaxially growing a p-type cap layer on the groove of the barrier layer with different thicknesses. Therefore, there is no need to face the difficulty of p-GaN ohmic contact preparation of the p-FET, that is: heavy doping of a p-GaN surface layer, metals using high work functions, and harsh process conditions; and there is also no need to face the problems of high defective state concentration and low hole mobility in a p-GaN material.

In an embodiment, the barrier layer includes a plurality of barrier sub-layers sequentially arranged on the channel layer.

Further, a groove structure is formed in at least one gate area of the barrier layer; the notch of the groove structure is distributed on the surface of the barrier layer; and a groove bottom is distributed in one barrier sub-layer, at an interface of the two adjacent barrier sub-layers, or the surface of the channel layer.

Alternatively, the groove structure is formed in at least one gate area of the barrier layer. The barrier layer includes a first barrier sub-layer and a second barrier sub-layer disposed on the first barrier sub-layer. The groove structure includes a first groove structure and a second groove structure. The first groove structure is formed in the first barrier sub-layer, and a local area of the second barrier sub-layer sinks into the first groove structure, so as to form the second groove structure.

In an embodiment, the HEMT structure further includes at least one insertion layer, and the insertion layer is distributed between the two barrier sub-layers.

In an embodiment, the groove structure is formed in at least one gate area of the barrier layer; the notch of the groove structure is distributed on the surface of the barrier layer; and the groove bottom is distributed in the insertion layer or an interface of the insertion layer and the adjacent barrier sub-layer.

Exemplarily, when the barrier layer is etched to form a gate groove, a GaN insertion layer may be used as a sacrificial layer for etching and thermal decomposition, so as to effectively remove lattice damage and surface staining, and thermal decomposition is automatically stopped at an AlGaN barrier layer below, such that device performance deterioration problems such as threshold voltage drift and large leakage caused by a gate interface state introduced by etching may be avoided, and the consistency of the thickness of the first gate area or the first gate area and the second gate area is guaranteed, thereby improving the uniformity of the device threshold voltages.

In an embodiment, a groove structure is formed in at least one gate area of the barrier layer; the notch of the groove structure is distributed on the surface of the barrier layer, and a groove bottom is distributed on the surface of the channel layer; and an inner wall of the groove structure is at least coated with continuous gate dielectric layers, and the gate dielectric layer is configured to separate a gate and the groove structure.

In an embodiment, the HEMT structure specifically includes a transition layer, a withstand voltage layer, the channel layer, and the barrier layer, which are sequentially grown on a substrate.

Some embodiments of the present application further provide a GaN-based HEMT device, which includes the GaN-based HEMT structure having a multi-threshold voltage, and a gate, a source, and a drain that cooperate with the HEMT structure. Each HEMT unit may be respectively provided with a gate, a source, and a drain. Materials and arrangement manners of the gate, the source, and the drain are all well known to those skilled in the art, and details are not described herein again.

In addition, the GaN-based HEMT structure or the GaN-based HEMT device may further include other structural layers such as a passivation layer and structures for electrically isolating a plurality of HEMT units, which, likewise, are also well known to those skilled in the art.

A method for preparing a GaN-based HEMT structure having a multi-threshold voltage provided in some embodiments of the present application includes the following operations.

A channel layer and a barrier layer are sequentially grown on a substrate.

A first source area, a second source area, a first gate area, a second gate area, a first drain area, and a second drain area are at least defined on the barrier layer, where the first source area, the first gate area, and the first drain area cooperate with each other, so as to form a first HEMT unit, the second source area, the second gate area, and the second drain area cooperate with each other, so as to form a second HEMT unit, the first HEMT unit has a first threshold voltage, and the second HEMT unit has a second threshold voltage.

When the barrier layer is grown, the thickness of the barrier layer in the first gate area is enabled to be less than that in the second gate area, or after the barrier layer is grown, a local area of the barrier layer is removed, to enable the thickness of the barrier layer in the first gate area to be less than that in the second gate area, so as to enable the first threshold voltage to be higher than the second threshold voltage.

In an embodiment, the preparation method specifically includes: after the barrier layer is grown, at least etching the first gate area, so as to at least form a groove structure in the first gate area.

In an embodiment, the preparation method specifically includes: first growing a first barrier sub-layer, and etching a first groove structure in a selected area of the first barrier sub-layer, where the selected area corresponds to the first gate area; and then growing a second barrier sub-layer on the first barrier sub-layer, enabling a local area of the second barrier sub-layer to sink into the first groove structure, and forming a second groove structure, so as to form the barrier layer.

In an embodiment, the preparation method specifically includes: sequentially growing a plurality of barrier sub-layers on the channel layer, and growing an insertion layer between at least two barrier sub-layers, so as to form the barrier layer.

In an embodiment, the preparation method specifically includes: growing a P-type layer on the barrier layer, so as to fill a local area of the P-type layer in the groove structure; and then removing the rest area of the P-type layer other than the gate areas by means of etching, so as to reduce or exhaust 2DEG under the plurality of barrier sub-layers of the barrier layer.

In an embodiment, the preparation method specifically includes: growing a gate dielectric layer on the barrier layer, and enabling the gate dielectric layer to at least continuously cover an inner wall of the groove structure.

In the present application, a dry etching or wet etching process commonly used in the art may be used to etch the barrier layer, so as to form the groove structure.

In the present application, the channel layer, the barrier layer, the P-type layer and the insertion layer may mainly be formed by a group III-V semiconductor compound, which is a GaN-based material, and especially formed by a group III nitride. For example, the material of the channel layer may be GaN; the material of the barrier layer may be AlGaN, AlInGaN, etc.; the material of the P-type layer may be GaN, AlGaN, etc.; the material of the insertion layer may be GaN, which is not limited herein; and the material of the gate dielectric layer may include silicon nitride or silicon oxide, which is not limited herein.

In the present application, the transition layer, the withstand voltage layer, the channel layer, and the barrier layer may be grown and formed by means of Hydride Vapor Phase Epitaxy (HVPE), Metal Organic Chemical Vapor Deposition (MOCVD), and Plasma Enhanced Chemical Vapor Deposition (PECVD) which are commonly used in the art, which is not limited herein.

In addition, the preparation method may further include other device processing processes known in the art. For example, a surface passivation layer is manufactured on a device structure; a gate, a source, and a drain are further manufactured after a dielectric layer is deposited; and metals are deposited on electrodes to prepare a field-plate structure, so as to form a final GaN-based HEMT device.

Exemplarily, in a typical implementation of the present application, the GaN-based HEMT structure includes an AlGaN/GaN heterojunction, and a method for performing secondary epitaxy on a p-GaN or AlGaN/p-GaN layer on the AlGaN barrier layer with and without grooves or a GaN channel layer is used; and then more than two p-GaN gates are prepared through patterning, so as to implement an enhanced device with high and low threshold voltages on the same wafer.

Specifically, for a gate groove area of the AlGaN barrier layer, the thickness of the barrier layer in the area is relatively small, such that the concentration of the 2DEG induced by the AlGaN/GaN heterojunction is relatively low; and after the secondary epitaxy of p-GaN or AlGaN/p-GaN, the 2DEG under the gate is easily exhausted, and an energy band is highly lifted, so as to form an HEMT unit with a high threshold voltage. For a gate area of the AlGaN barrier layer that has no grooves, the thickness of the barrier layer in the area is relatively large, and an HEMT unit with a low threshold voltage is formed at a p-GaN gate prepared through secondary epitaxy as the barrier layer is thick. The thicknesses of the AlGaN barrier layers of the two HEMT units are controlled by processing devices such as the high-accuracy MOCVD, such that the uniformity of the threshold voltages is guaranteed.

The enhanced GaN-based HEMT structure with more than two threshold voltages can be implemented on the same wafer according to the process of the present application, and is compatible in preparation process with the conventional group III-V semiconductor devices, such that the HEMT structure is suitable for industrial production, and can effectively guaranteed the uniformity of the threshold voltages of the GaN-based HEMT structure and the reliability of the devices.

In particular, when an AlGaN/GaN/AlGaN composite structure is used as the barrier layer of the GaN-based HEMT, the introduced GaN insertion layer may be used as a sacrificial layer for etching and thermal decomposition in the first gate area, so as to guaranteed the thickness of the AlGaN barrier layer in the gate area and effectively remove etching damage, such that the uniformity of the threshold voltages of the devices and the reliability of the devices are effectively guaranteed.

Some embodiments of the present application further provide a high and low threshold logic circuit, which includes the GaN-based HEMT structure having a multi-threshold voltage. Compared with a circuit in which a depleted/enhanced GaN HEMT forms a cooperation, the circuit in which the enhanced GaN HEMT with various threshold voltages forms a cooperation has lower power consumption and higher safety. In addition, the various enhanced GaN HEMTs all use high-mobility 2DEG as the conductive channels, which have the capabilities of rapid on-off, and the logic circuit manufactured through cooperation has a faster calculation speed and a stronger anti-interference capability.

In brief, according to the present application, high-uniformity high and low threshold voltage enhanced HEMTs may be implemented on a GaN-based wafer, and a basic device requirement of a 1/2 logic circuit is met. In addition, compared with an existing p-FET, the GaN-based HEMT structure of the present application has higher reliability. Compared with an existing complementary logic circuit, the logic circuit implemented by the GaN-based HEMT structure of the present application uses the high-mobility 2DEG as the conductive channels, such that the logic circuit has the characteristics of rapid on-off speed and high integration.

The technical solutions of the present application will be described in more detail below in combination with the drawings and several embodiments, but it should be understood that the following embodiments are intended only to explain and illustrate the technical solutions, but do not limit the scope of the present application. Postscript, unless otherwise specified, the various raw materials, reaction devices, testing devices and methods used in the following embodiments are known in the art.

### Embodiment 1

Referring to FIG. 2 to FIG. 6, a method for preparing a GaN-based HEMT device having a multi-threshold voltage provided in this embodiment includes the following steps.

At S1, an MOCVD method is used; an AlN/AlGaN transition layer 102 with the thickness being about 300 nm, a C-doped Al0.07Ga0.93N high resistance layer 103 with the thickness being about 4 μm, an unintentional doped GaN layer 104 with the thickness being about 150 nm, a first AlGaN barrier sub-layer 105A with the thickness being about 12 nm, a GaN insertion layer 106A with the thickness being about 4 nm, and a second AlGaN barrier sub-layer 105B with the thickness being about 4 nm are sequentially grown on a Si<111> substrate 101, as shown in FIG. 2. The first AlGaN barrier sub-layer 105A and the second AlGaN barrier sub-layer 105B form a barrier layer.

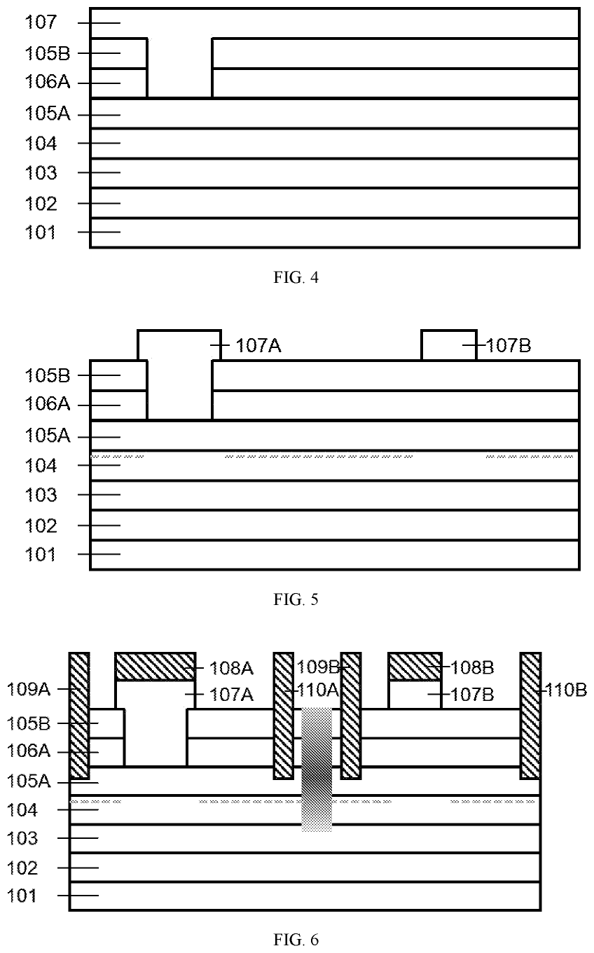

At S2, photoresist is used as a mask; and after photoetching patterning, an ICP etching method is used to remove a first gate area of the second AlGaN barrier sub-layer 105B by about 6 nm in a thickness direction, so as to form a groove structure, as shown in FIG. 3. After wet surface treatment and MOCVD high temperature thermal decomposition treatment, the groove structure is ended at the surface of the first AlGaN barrier sub-layer 105A; and then secondary epitaxy is performed on a p-type GaN layer of which thickness is about 80 nm and a Mg doping concentration is 2-5×10¹⁹/cm³, as shown in FIG. 4.

At S3, the photoresist is used as the mask; and after photoetching patterning, a dry etching method is used to remove the p-GaN layer in a non-gate area, and etching is stopped at the surface of the first AlGaN barrier sub-layer 105A, so as to prepare a first p-GaN layer 107A (which may also be named as a first P-type gate) in the first gate area, and prepare a second p-GaN layer 107B (which may also be named as a second P-type gate) in a second gate area of the second AlGaN barrier sub-layer 105B, as shown in FIG. 5.

At S4, organic cleaning methods such as acetone are used to remove the photoresist, and the heights of the two P-type gates are about 80 nm through testing. Then hydrofluoric acid (HF) is used to remove an oxide layer on the surface of the barrier layer, and rapid annealing is performed at an atmosphere of 500° C. and N₂, so as to recover 2DEG at an AlGaN/GaN heterojunction. Then, Ti/Au is deposited on the two P-type gates; a first schottky gate contact metal 108A and a second schottky gate contact metal 108B are prepared after annealing; Ti/Al/Ti/Au is respectively deposited in each source area and drain area of the barrier layer, so as to respectively form a first source contact metal 109A, a second source contact metal 109B, a first drain contact metal 110A, and a second drain contact metal 110B; and an ohmic contact is prepared after annealing. Then, a transistor unit A with a high threshold voltage is formed through the cooperation of the first schottky gate contact metal 108A, the first source contact metal 109A, and the first drain contact metal 110A; and a transistor unit B with a low threshold voltage is formed through the cooperation of the second schottky gate contact metal 108B, the second source contact metal 109B, and the second drain contact metal 110B.

The structure of a GaN-based HEMT device finally prepared in this embodiment is shown in FIG. 6.

I-V methods are used to perform gate transfer characteristic testing on the GaN-based HEMT device, so as to obtain the mean value of threshold voltages of the transistor unit A to be about 2.1 V, and the mean value of threshold voltages of the transistor unit B to be about 1.3 V. A test result verifies that, according to the solution of this embodiment, a p-type gate enhanced HEMT with high and low threshold voltages may be prepared on the same wafer.

### Embodiment 2

A method for preparing a GaN-based HEMT device having a multi-threshold voltage provided in this embodiment includes the following steps.

At S1, referring to S1 in Embodiment 1, an AlN/AlGaN transition layer 202, a C-doped Al_{0.07}Ga_{0.93}N high resistance layer 203, an unintentional doped GaN layer 204, and an AlGaN barrier layer 205A with the thickness being about 18-25 nm are sequentially grown on a substrate 201 by using the MOCVD method.

At S2, referring to S2 in Embodiment 1, photoresist is used as a mask; and after photoetching patterning, an ICP etching method is used to remove a portion (for example, about 6 nm) from a first gate area of the AlGaN barrier layer 205A in a thickness direction, so as to form a groove structure. After wet surface treatment and MOCVD high temperature thermal decomposition treatment, the groove structure is ended at a certain depth (8-20 nm from a groove bottom to a channel layer) in the AlGaN barrier layer 205A, and then secondary epitaxy is performed on a p-type GaN layer or a p-type AlGaN layer (referred to as p-type cap layer).

At S3, referring to S3 in Embodiment 1, the photoresist is used as the mask; and after photoetching patterning, a dry etching method is used to remove the p-type cap layer in a non-gate area, and etching is stopped at the surface of the AlGaN barrier layer 205A, so as to prepare a first p-type cap layer 207A (which may also be named as a first P-type gate) in the first gate area, and prepare a second p-type cap layer 207B (which may also be named as a second P-type gate) in a second gate area of the AlGaN barrier layer 205A.

At S4, referring to S4 in Embodiment 1, organic cleaning methods such as acetone are used to remove the photoresist, then hydrofluoric acid (HF) is used to remove an oxide layer on the surface of the barrier layer, and rapid annealing is then performed, so as to recover 2DEG at an AlGaN/GaN heterojunction. Then, Ti/Au is deposited on the two P-type gates; a first schottky gate contact metal 208A and a second schottky gate contact metal 208B are prepared after annealing; Ti/Al/Ti/Au is respectively deposited in each source area and drain area of the barrier layer, so as to respectively form a first source contact metal 209A, a second source contact metal 209B, a first drain contact metal 210A, and a second drain contact metal 210B; and an ohmic contact is prepared after annealing. Then, a transistor unit A with a high threshold voltage is formed through the cooperation of the first schottky gate contact metal 208A, the first source contact metal 209A, and the first drain contact metal 210A; and a transistor unit B with a low threshold voltage is formed through the cooperation of the second schottky gate contact metal 208B, the second source contact metal 209B, and the second drain contact metal 210B.

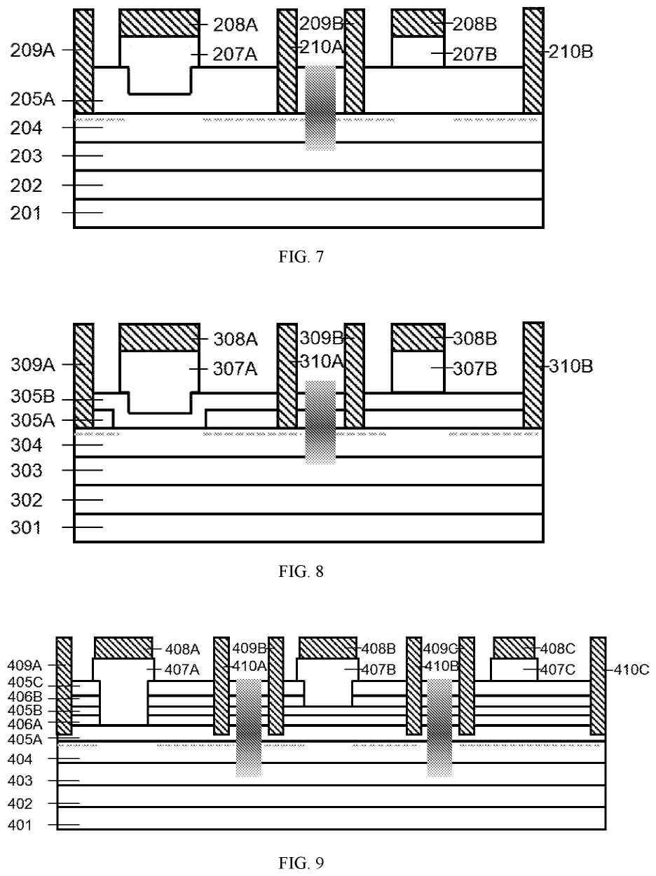

The structure of a GaN-based HEMT device finally prepared in this embodiment is shown in FIG. 7.

Gate transfer characteristic testing is performed on the GaN-based HEMT device in this embodiment, so as to obtain the mean value of threshold voltages of the transistor unit A to be about 2.3V, and the mean value of threshold voltages of the transistor unit B to be about 1.1V.

### Embodiment 3

A method for preparing a GaN-based HEMT device having a multi-threshold voltage provided in this embodiment includes the following steps.

At S1, referring to S1 in Embodiment 1, an AlN/AlGaN transition layer 302, a C-doped Al_{0.07}Ga_{0.93}N high resistance layer 303, an unintentional doped GaN layer 304, and a first AlGaN barrier sub-layer 305A with the thickness being about 2-10 nm are sequentially grown on a substrate 301 by using the MOCVD method. Then a left-side gate area of the first AlGaN barrier sub-layer 305A is completely removed by means of patterning etching; then secondary epitaxy is performed on a GaN layer with the thickness being about 0-10 nm, an AlGaN layer with the thickness being about 5-15 nm, and a p-(Al) GaN layer with the thickness being about 70 nm, so as to form a laminated structure 305B (preferably, the thickness of the GaN layer is about 5 nm, and the thickness of the AlGaN layer is about 10 nm).

At S2, referring to S2-S3 in Embodiment 1, a first p-type layer 307A (which may also be named as a first P-type gate) is prepared in a first gate area of the laminated structure 305B, and a second p-type layer 307B (which may also be named as a second P-type gate) is prepared in a second gate area of the laminated structure 305B.

At S3, referring to S4 in Embodiment 1, a first schottky gate contact metal 308A, a second schottky gate contact metal 308B, a first source contact metal 309A, a second source contact metal 309B, a first drain contact metal 310A, and a second drain contact metal 310B are respectively manufactured. Then, a transistor unit A with a high threshold voltage is formed through the cooperation of the first schottky gate contact metal 308A, the first source contact metal 309A, and the first drain contact metal 310A; and a transistor unit B with a low threshold voltage is formed through the cooperation of the second schottky gate contact metal 308B, the second source contact metal 309B, and the second drain contact metal 310B.

The structure of a GaN-based HEMT device finally prepared in this embodiment is shown in FIG. 8.

Gate transfer characteristic testing is performed on the GaN-based HEMT device in this embodiment, so as to obtain the mean value of threshold voltages of the transistor unit A to be about 2.3V, and the mean value of threshold voltages of the transistor unit B to be about 1.3V.

### Embodiment 4

A method for preparing a GaN-based HEMT device having a multi-threshold voltage provided in this embodiment includes the following steps.

At S1, referring to S1 in Embodiment 1, an AlN/AlGaN transition layer 402, a C-doped Al_{0.07}Ga_{0.93}N high resistance layer 403, an unintentional doped GaN layer 404, a first AlGaN barrier sub-layer 405A, a first GaN insertion layer 406A, a second AlGaN barrier sub-layer 405B, a second GaN insertion layer 406B, and a third AlGaN barrier sub-layer 405C are sequentially grown on a substrate 401 by using the MOCVD method.

At S2, referring to S2 in Embodiment 1, photoresist is used as a mask; after photoetching patterning, an ICP etching method is used to remove a part of a first gate area and a second gate area of the AlGaN barrier layer in a thickness direction, so as to respectively form a first groove structure and a second groove structure; a groove bottom surface of the first groove structure is located on the surface of the first AlGaN barrier sub-layer 405A, and a groove bottom surface of the second groove structure is located on the surface of the second AlGaN barrier sub-layer 405B; and a third gate area of the AlGaN barrier layer is not etched.

At S3, secondary epitaxy is performed on a GaN layer with the thickness being about 0-10 nm, an AlGaN layer with the thickness being about 0-10 nm, and a p-(Al) GaN layer with the thickness being about 70 nm on the AlGaN barrier layer, so as to form a laminated structure (which may also be considered as a P-type layer). Preferably, the thickness of the GaN layer in the laminated structure is about 5 nm, and the thickness of the AlGaN layer is about 5 nm.

At S4, referring to S3 in Embodiment 1, a first p-type layer 407A, a second p-type layer 407B, and a third p-type layer 407C are respectively prepared in the first gate area, the second gate area, and the third gate area.

At S5, referring to S4 in Embodiment 1, a first schottky gate contact metal 408A, a second schottky gate contact metal 408B, a third schottky gate contact metal 408C, a first source contact metal 409A, a second source contact metal 409B, a third source contact metal 409C, a first drain contact metal 310A, a second drain contact metal 310B, and a third drain contact metal 310C are respectively manufactured. Then, a transistor unit A is formed through the cooperation of the first schottky gate contact metal 308A, the first source contact metal 309A, and the first drain contact metal 310A; a transistor unit B is formed through the cooperation of the second schottky gate contact metal 308B, the second source contact metal 309B, and the second drain contact metal 310B; and a transistor unit C is formed through the cooperation of the third schottky gate contact metal 308C, the third source contact metal 309C, and the third drain contact metal 310C.

The structure of a GaN-based HEMT device finally prepared in this embodiment is shown in FIG. 9.

Gate transfer characteristic testing is performed on the GaN-based HEMT device in this embodiment, so as to obtain the mean value of threshold voltages of the transistor unit A to be about 2.4V, the mean value of threshold voltages of the transistor unit B to be about 1.3V, and the mean value of threshold voltages of the transistor unit C to be about-2.0V.

### Embodiment 5

A method for preparing a GaN-based HEMT device having a multi-threshold voltage provided in this embodiment includes the following steps.

At S1, referring to S1 in Embodiment 1, an AlN/AlGaN transition layer 502, a high resistance (Al) GaN withstand voltage layer 503, an (Al) GaN conductive channel layer 504, and an AlGaN barrier layer 505 are sequentially grown on a substrate 501 by using the MOCVD method.

At S2, referring to S2 in Embodiment 1, photoresist is used as a mask; after photoetching patterning, an ICP etching method is used to remove a first gate area of the AlGaN barrier layer 505 in a thickness direction, so as to form a groove structure, and the groove structure is ended at the surface of the (Al) GaN conductive channel layer 504; and a second gate area of the AlGaN barrier layer 505 is not etched.

At S3, an insulating gate dielectric layer 506 (with the thickness being about 1-20 nm) such as aluminum nitride is deposited on the surface of the AlGaN barrier layer 505; then referring to S4 in Embodiment 1, a first schottky gate contact metal 508A, a second schottky gate contact metal 508B, a first source contact metal 509A, a second source contact metal 509B, a first drain contact metal 510A, and a second drain contact metal 510B are respectively manufactured. The first schottky gate contact metal and the second schottky gate contact metal preferably use metals with high work functions, such as Ni and Pd. Then, a transistor unit A with a high threshold voltage is formed through the cooperation of the first schottky gate contact metal 508A, the first source contact metal 509A, and the first drain contact metal 510A; and a transistor unit B with a low threshold voltage is formed through the cooperation of the second schottky gate contact metal 508B, the second source contact metal 509B, and the second drain contact metal 510B.

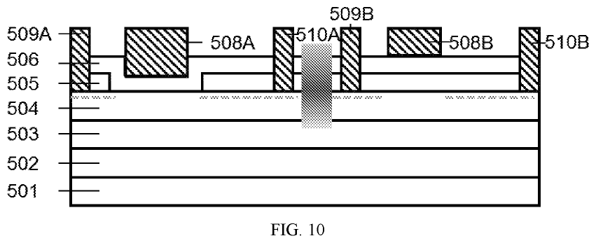

The structure of a GaN-based HEMT device finally prepared in this embodiment is shown in FIG. 10.

According to the above embodiments of the present application, wafer-level preparation of high and low threshold voltage devices is realized by accurately controlling the thickness of the barrier layer or the dielectric layer in the gate area of the device; and the prepared multi-threshold voltage HEMT is high in integrate, high in carrier mobility, and desirable in uniformity of the threshold voltages, such that the HEMT may be used for functional circuits based on Logic 1/2.

It is to be noted that, the above descriptions are only preferred embodiments of the present application and are not intended to limit the present application. Although the present application is described in detail with reference to the foregoing embodiments, it is still possible for a person skilled in the art to modify the technical solutions described in the foregoing embodiments or to make equivalent substitutions for some of the technical features, and any modifications, equivalent substitutions, improvements, etc. made within the spirit and principles of the present application shall be included in the scope of protection of the present application.

1. A GaN-based High Electron Mobility Transistor (HEMT) structure having a multi-threshold voltage, comprising a channel layer and a barrier layer, wherein a Two-dimensional Electron Gas (2DEG) is formed between the channel layer and the barrier layer; the barrier layer is at least provided with a first source area, a second source area, a first gate area, a second gate area, a first drain area, and a second drain area; the first source area, the first gate area, and the first drain area cooperate with each other to form a first HEMT unit, and the first HEMT unit has a first threshold voltage; the second source area, the second gate area, and the second drain area cooperate with each other to form a second HEMT unit, and the second HEMT unit has a second threshold voltage; and a thickness of the barrier layer in the first gate area is less than a thickness of the barrier layer in the second gate area to enable the first threshold voltage to be higher than the second threshold voltage.

2. The GaN-based HEMT structure having the multi-threshold voltage according to claim 1, wherein the barrier layer is further provided with a third source area, a third gate area, and a third drain area; the third source area, the third gate area, and the third drain area cooperate with each other to form a third HEMT unit, and the third HEMT unit has a third threshold voltage; and the thickness of the barrier layer in the second gate area is less than a thickness of the barrier layer in the third gate area to enable the first threshold voltage>the second threshold voltage>the third threshold voltage.

3. The GaN-based HEMT structure having the multi-threshold voltage according to claim 1, further comprising a P-type layer, wherein the P-type layer is disposed on a plurality of gate areas of the barrier layer comprising the first gate area and the second gate area, and the P-type layer is configured to reduce or exhaust the 2DEG under the plurality of gate areas of the barrier layer.

4. The GaN-based HEMT structure having the multi-threshold voltage according to claim 3, wherein a groove structure is formed in at least one of the plurality of gate areas of the barrier layer; and the P-type layer distributed on the plurality of gate areas is at least partially filled in the groove structure.

5. The GaN-based HEMT structure having the multi-threshold voltage according to claim 1, wherein the barrier layer comprises a plurality of barrier sub-layers sequentially arranged on the channel layer.

6. The GaN-based HEMT structure having the multi-threshold voltage according to claim 5, wherein a groove structure is formed in at least one of the first gate area and the second gate area of the barrier layer; a notch of the groove structure is distributed on a surface of the barrier layer; and a groove bottom is distributed in one of the plurality of barrier sub-layers, at an interface of two adjacent barrier sub-layers, or a surface of the channel layer, or
the groove structure is formed in at least one of the first gate area and the second gate area of the barrier layer; the barrier layer comprises a first barrier sub-layer and a second barrier sub-layer disposed on the first barrier sub-layer; the groove structure comprises a first groove structure and a second groove structure; and the first groove structure is formed in the first barrier sub-layer, and a local area of the second barrier sub-layer sinks into the first groove structure to form the second groove structure; and/or
the GaN-based HEMT structure further comprises at least one insertion layer, and the at least one insertion layer is distributed between two barrier sub-layers.

7. The GaN-based HEMT structure having the multi-threshold voltage according to claim 6, wherein the groove structure is formed in at least one of the first gate area and the second gate area of the barrier layer; the notch of the groove structure is distributed on the surface of the barrier layer; and the groove bottom is distributed in the at least one insertion layer or an interface of the at least one insertion layer and an adjacent barrier sub-layer.

8. The GaN-based HEMT structure having the multi-threshold voltage according to claim 1, wherein a groove structure is formed in at least one of the first gate area and the second gate area of the barrier layer; a notch of the groove structure is distributed on a surface of the barrier layer, and a groove bottom is distributed on a surface of the channel layer; and an inner wall of the groove structure is at least coated with continuous gate dielectric layers, and each of the continuous gate dielectric layers is configured to separate a gate and the groove structure.

9. The GaN-based HEMT structure having the multi-threshold voltage according to claim 1, specifically comprising a transition layer, a withstand voltage layer, the channel layer, and the barrier layer sequentially grown on a substrate.

10. A method for preparing a GaN-based HEMT structure having a multi-threshold voltage, comprising:
sequentially growing a channel layer and a barrier layer on a substrate;
at least defining a first source area, a second source area, a first gate area, a second gate area, a first drain area, and a second drain area on the barrier layer, wherein the first source area, the first gate area, and the first drain area cooperate with each other to form a first HEMT unit, the second source area, the second gate area, and the second drain area cooperate with each other to form a second HEMT unit, the first HEMT unit has a first threshold voltage, and the second HEMT unit has a second threshold voltage; and
when the barrier layer is grown, enabling a thickness of the barrier layer in the first gate area to be less than a thickness of the barrier layer in the second gate area, or after the barrier layer is grown, removing a local area of the barrier layer, enabling the thickness of the barrier layer in the first gate area to be less than the thickness of the barrier layer in the second gate area to enable the first threshold voltage to be higher than the second threshold voltage.

11. The method for preparing the GaN-based HEMT structure having the multi-threshold voltage according to claim 10, specifically comprising:
after the barrier layer is grown, at least etching the first gate area to at least form a groove structure in the first gate area; or
first growing a first barrier sub-layer, and etching a first groove structure in a selected area of the first barrier sub-layer, wherein the selected area corresponds to the first gate area;
and then growing a second barrier sub-layer on the first barrier sub-layer, enabling a local area of the second barrier sub-layer to sink into the first groove structure, and forming a second groove structure to form the barrier layer.

12. The method for preparing the GaN-based HEMT structure having the multi-threshold voltage according to claim 10, specifically comprising: sequentially growing a plurality of barrier sub-layers on the channel layer, and growing an insertion layer between at least two of the plurality of barrier sub-layers to form the barrier layer.

13. The method for preparing the GaN-based HEMT structure having the multi-threshold voltage according to claim 11, specifically comprising: growing a P-type layer on the barrier layer to fill a local area of the P-type layer in the groove structure; and then removing a rest area of the P-type layer other than the gate areas by etching to reduce or exhaust (2DEG) under the barrier sub-layers of the barrier layer.

14. The method for preparing the GaN-based HEMT structure having the multi-threshold voltage according to claim 11, specifically comprising: growing a gate dielectric layer on the barrier layer, and enabling the gate dielectric layer to at least continuously cover an inner wall of the groove structure.

15. A method of an application of the GaN-based HEMT structure having the multi-threshold voltage according to claim 1 in a manufacturing of high and low threshold logic circuits.

16. The method for preparing the GaN-based HEMT structure having the multi-threshold voltage according to claim 11, specifically comprising: sequentially growing a plurality of barrier sub-layers on the channel layer, and growing an insertion layer between at least two of the plurality of barrier sub-layers to form the barrier layer.

17. The method according to claim 15, wherein in the GaN-based HEMT structure having the multi-threshold voltage, the barrier layer is further provided with a third source area, a third gate area, and a third drain area; the third source area, the third gate area, and the third drain area cooperate with each other to form a third HEMT unit, and the third HEMT unit has a third threshold voltage; and the thickness of the barrier layer in the second gate area is less than a thickness of the barrier layer in the third gate area to enable the first threshold voltage>the second threshold voltage>the third threshold voltage.

18. The method according to claim 15, wherein the GaN-based HEMT structure having the multi-threshold voltage further comprises a P-type layer, wherein the P-type layer is disposed on a plurality of gate areas of the barrier layer comprising the first gate area and the second gate area, and the P-type layer is configured to reduce or exhaust the 2DEG under the plurality of gate areas of the barrier layer.

19. The method according to claim 18, wherein in the GaN-based HEMT structure having the multi-threshold voltage, a groove structure is formed in at least one of the plurality of gate areas of the barrier layer; and the P-type layer distributed on the plurality of gate areas is at least partially filled in the groove structure.

20. The method according to claim 15, wherein in the GaN-based HEMT structure having the multi-threshold voltage, the barrier layer comprises a plurality of barrier sub-layers sequentially arranged on the channel layer.
